(19) United States
(12) Patent Application Publication
(10) Pub. No.: US 2013/0161669 A1
(43) Pub. Date: Jun. 27, 2013

(54) LIGHT-EMITTING DIODE WITH CURRENT DIFFUSION STRUCTURE AND A METHOD FOR FABRICATING THE SAME

(71) Applicants: Fu-Bang Chen, Taichung City (TW); Wei-Yu Yen, Taichung City (TW); Chih-Sung Chang, Taichung City (TW)

(72) Inventors: Fu-Bang Chen, Taichung City (TW); Wei-Yu Yen, Taichung City (TW); Chih-Sung Chang, Taichung City (TW)

(21) Appl. No.: 13/336,720

(22) Filed: Dec. 23, 2011

(51) Int. Cl. H01L 33/60; H01L 33/22

(52) U.S. Cl. 257/98; 438/29; 257/E33.06; 257/E33.062

(57) ABSTRACT

An LED with a current diffusion structure comprises an N-type semiconductor layer, a light emitting layer, a P-type semiconductor layer, an N-type electrode, a P-type electrode and a current blocking layer. The N-type semiconductor layer, light emitting layer and P-type semiconductor layer form a sandwich structure. The N-type and P-type electrodes are respectively arranged on the N-type and P-type semiconductor layers. The current blocking layer has the pattern of the N-type electrode and is embedded inside the N-type semiconductor layer. Thereby not only current generated by the N-type electrode detours the current blocking layer and uniformly passes through the light emitting layer, but also prevents interface effect to increase impedance. Thus is promoted lighting efficiency of LED. Further, as main light-emitting regions of the light emitting layer are far from the N-type electrode, light shielded by the N-type electrode is reduced and illumination of LED is thus enhanced.

### FIELD OF THE INVENTION

The present invention relates to a light-emitting diode, particularly to a light-emitting diode having high luminous efficiency.

### BACKGROUND OF THE INVENTION

A light-emitting diode (LED) is mainly formed via epitaxially growing semiconductor materials. For example, a blue LED is mainly made of gallium nitride (GaN)-based epitaxial films, wherein an N-type semiconductor layer, a light emitting layer and a P-type semiconductor layer are stacked to form a sandwich structure.

Refer to FIG. 1 for a conventional horizontal structure LED 1. In the conventional horizontal structure LED 1, a current blocking layer 3 is arranged inside a P-type semiconductor 2 to spread current and allow a light emitting layer 4 to uniformly emit light so as to increase the lighting efficiency. In the conventional horizontal structure LED 1, a P-type electrode 5 is normally made of a transparent electrically-conductive material, such as indium tin oxide (ITO) to increase the transmittance of light lest too much light is blocked by the electrode. However, ITO has poor electric conductivity and is likely to have an interface effect to cause increasing of impedance. Therefore, the luminous efficiency of the conventional horizontal structure LED 1 is intrinsically limited and hard to effectively increase.

Refer to FIG. 2 for a conventional vertical structure LED 6. The conventional vertical structure LED 6 needn't adopt a transparent electrically-conductive layer and thus is exempted from the problem of poor electric conductivity of ITO. In the conventional vertical structure LED 6, a current blocking layer 7 is arranged between a P-type semiconductor 8 and a P-type electrode 9. Thus is reduced the contact area of the P-type semiconductor 8 and the P-type electrode 9. The decreased contact area would increase the impedance and make the lighting efficiency hard to enhance.

Obviously, the conventional technologies cannot spread current without increasing impedance. Therefore, the conventional technologies are unlikely to effectively promote the luminous efficiency.

### SUMMARY OF THE INVENTION

The primary objective of the present invention is to provide an LED structure, thereby the contact impedance can be effectively controlled to obviously enhance the lighting efficiency.

Another objective of the present invention is to provide a method for fabricating an LED structure, thereby the contact impedance can be effectively controlled to obviously enhance the lighting efficiency.

The present invention proposes an LED with a current diffusion structure, which comprises an N-type semiconductor layer, a light emitting layer, a P-type semiconductor layer, an N-type electrode, a P-type electrode, and a current blocking layer. The light emitting layer is arranged on one side of the N-type semiconductor layer. The P-type semiconductor layer is arranged on one side of the light emitting layer, which is far from the N-type semiconductor layer. The N-type electrode has a pattern and is arranged on another side of the N-type semiconductor layer, which is far from the light emitting layer. The P-type electrode is arranged on one side of the P-type semiconductor layer, which is far from the light emitting layer. The current blocking layer has the pattern of the N-type electrode and embedded inside the N-type semiconductor layer.

The present invention also proposes a method for fabricating a light-emitting diode with a current diffusion structure, which comprises steps of: forming an N-type semiconductor layer on a temporary substrate; forming a current blocking layer embedded inside the N-type semiconductor layer; forming a light emitting layer; forming a P-type semiconductor layer; bonding the above-mentioned structure onto a permanent substrate; removing the temporary substrate; and coating an N-type electrode and a P-type electrode.

In the present invention, the current blocking layer embedded inside the N-type semiconductor layer not only can spread the current, but also can effectively control the contact impedance. Further, as the main light-emitting regions of the light emitting layer are far from the N-type electrode, the light shielded by the N-type electrode can be reduced. Therefore, the present invention can obviously promote the luminous efficiency.

### BRIEF DESCRIPTION OF THE DRAWINGS

FIG. 1 schematically shows a conventional horizontal structure LED;

FIG. 2 schematically shows a conventional vertical structure LED;

FIG. 3A schematically shows the structure of an LED with a current diffusion structure according to one embodiment of the present invention;

FIG. 3B schematically shows the current distribution of an LED with a current diffusion structure according to one embodiment of the present invention; and

FIGS. 4A-4E schematically show the steps of a method for fabricating an LED with a current diffusion structure according to one embodiment of the present invention.

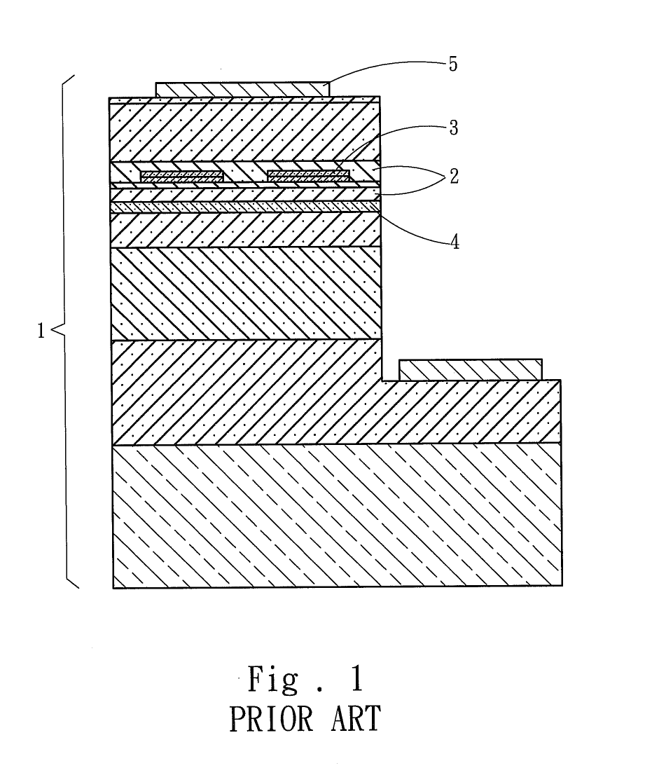

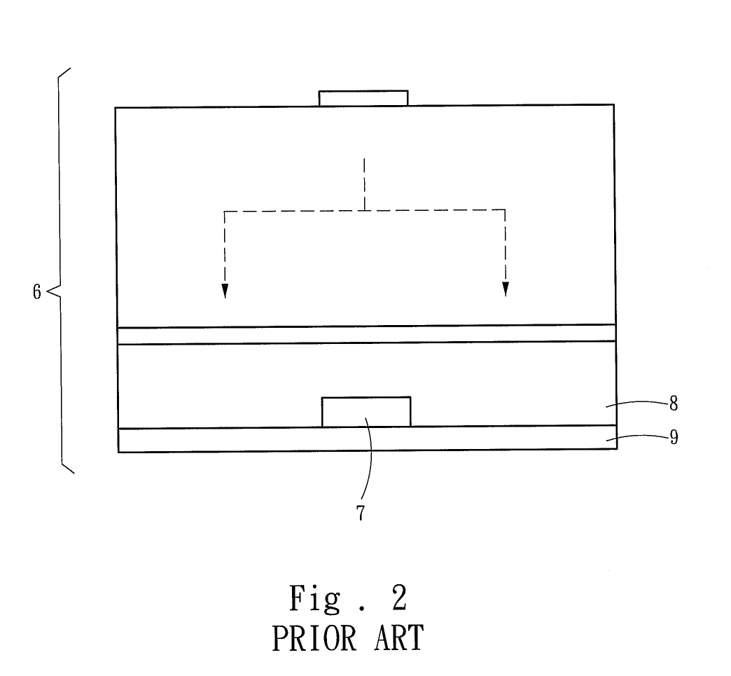

### DETAILED DESCRIPTION OF THE PREFERRED EMBODIMENTS

The technical contents of the present invention are described in detail with embodiments. However, it should be understood that the embodiments are only to exemplify the present invention but not to limit the scope of the present invention.

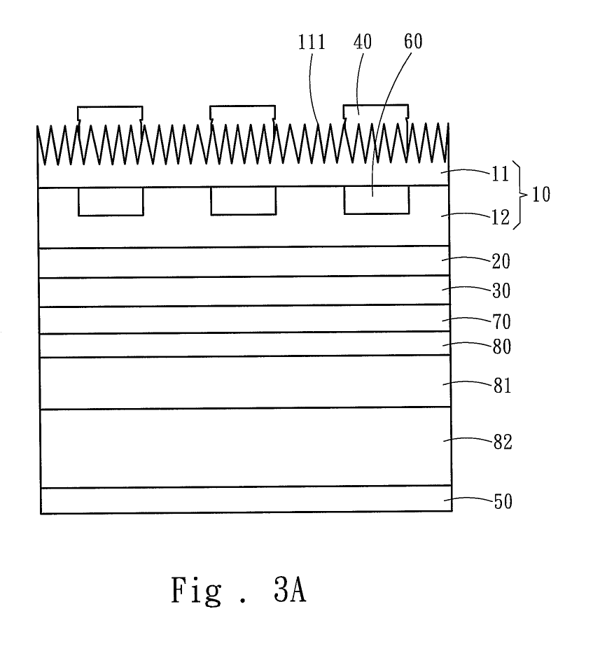

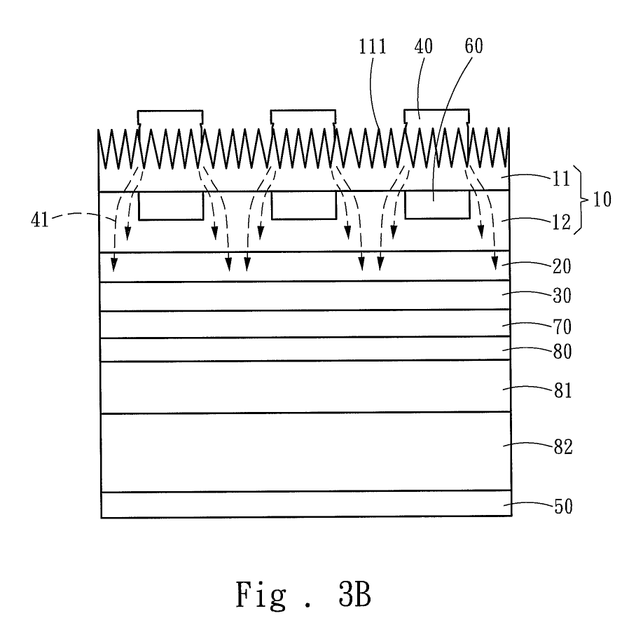

Refer to FIG. 3A. The present invention proposes an LED with a current diffusion structure, which comprises an N-type semiconductor layer 10, a light emitting layer 20, a P-type semiconductor layer 30, an N-type electrode 40, a P-type electrode 50 and a current blocking layer 60. The light emitting layer 20 is arranged on one side of the N-type semiconductor layer 10. The P-type semiconductor layer 30 is arranged on one side of the light emitting layer 20, which is far from the N-type semiconductor layer 10. The N-type electrode 40 has a pattern and is arranged on another side of the N-type semiconductor layer 10, which is far from the light emitting layer 20. The P-type electrode 50 is arranged on one side of the P-type semiconductor layer 30, which is far from the light emitting layer 20.

In one embodiment, the light emitting layer 20 is made of gallium nitride or gallium indium nitride. In one embodiment, the N-type semiconductor layer 10 is made of silicon-doped gallium nitride, gallium aluminum nitride, or gallium indium aluminum nitride. In one embodiment, the P-type semiconductor layer 30 is made of magnesium-doped gallium nitride, gallium aluminum nitride, or gallium indium aluminum nitride.

The current blocking layer 60 has the pattern of the N-type electrode 40 and embedded inside the N-type semiconductor layer 10. The N-type semiconductor layer 10 includes a first N-type semiconductor layer 11 and a second N-type semiconductor layer 12. The current blocking layer 60 is arranged between the first N-type semiconductor layer 11 and the second N-type semiconductor layer 12. In one embodiment, the current blocking layer 60 is made of metal oxide selected from a group consisting of titanium dioxide and silicon dioxide. The current blocking layer 60 has a thickness of 10-500 nm. The surface 111 of the first N-type semiconductor layer 11 is roughened to increase the contact area with the N-type electrode 40.

In one embodiment, a metal reflection layer 70 is arranged between the P-type electrode 50 and the P-type semiconductor layer 30. In one embodiment, the metal reflection layer 70 is made of a material selected from a group consisting of aluminum, nickel, silver and titanium. The metal reflection layer 70 reflects the light emitted by the light emitting layer 20 to promote the lighting efficiency. The metal reflection layer 70 also functions to conduct electricity.

In one embodiment, a barrier layer 80, a bonding layer 81 and a permanent substrate 82 are arranged between the metal reflection layer 70 and the P-type electrode 50. In one embodiment, the barrier layer 80 is made of a material selected from a group consisting of titanium, tungsten, platinum, nickel, aluminum and chromium. The barrier layer 80 is used to prevent the P-type semiconductor layer 30 from being damaged while bonding to the bonding layer 81. The barrier layer 80 also functions to conduct electricity and dissipate heat. In one embodiment, the bonding layer 81 is made of a material selected from a group consisting of gold-tin alloys, gold-indium alloys, and gold-lead alloys. The bonding layer 81 functions to conduct electricity, dissipate heat, and perform adhesion. In one embodiment, the permanent substrate 82 is made of a material selected from a group consisting of silicon, copper, copper-tungsten alloys, aluminum nitride, and titanium nitride. In addition to functioning as a substrate, the permanent substrate 82 also functions to conduct electricity and improve the heat-dissipating efficiency.

Refer to FIG. 3B. The current blocking layer 60 of the present invention is embedded inside the N-type semiconductor layer 10 to allow the current 41 generated by the N-type electrode 40 to detour the current blocking layer 60 and uniformly pass through the light emitting layer 20. The current blocking layer 60 can prevent an interface effect to increase the impedance. Further, as the main light-emitting regions of the light emitting layer 20 (i.e. the regions where the current 41 passes in high density) are far from the N-type electrode 40, the light shielded by the N-type electrode 40 is reduced. Therefore, the illumination of the LED is enhanced.

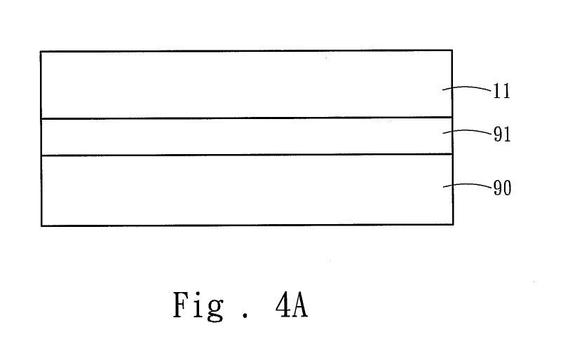

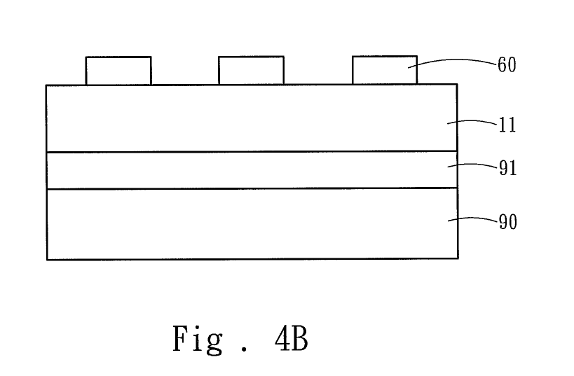

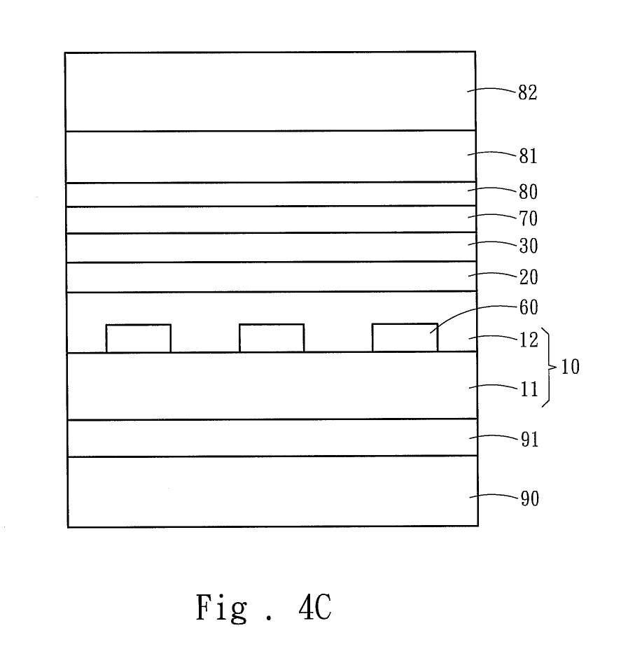

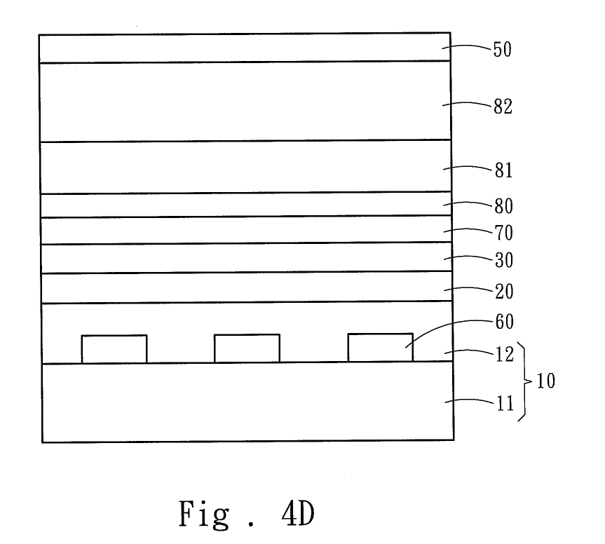

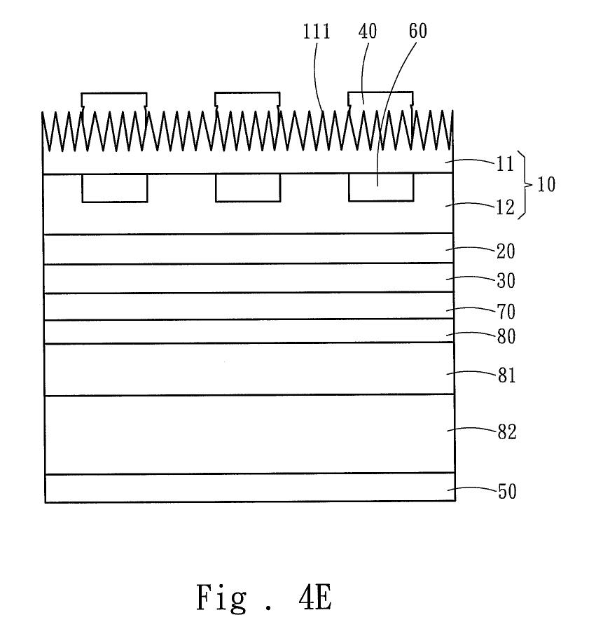

Refer to FIGS. 4A-4E for the steps of a method for fabricating an LED with a current diffusion structure.

Refer to FIG. 4A. Firstly, a first N-type semiconductor layer 11 is grown on a temporary substrate 90. In one embodiment, the N-type semiconductor layer 11 is made of silicon-doped gallium nitride, gallium aluminum nitride or gallium indium aluminum nitride. In one embodiment, a buffer semiconductor layer 91 is formed on the temporary substrate 90 before the first N-type semiconductor layer is grown on the temporary substrate 90. The buffer semiconductor layer 91 can reduce the defects of the first N-type semiconductor layer 11. In one embodiment, the temporary substrate 90 is made of sapphire, which favors crystal growth. In one embodiment, the buffer semiconductor layer 91 is made of undoped gallium nitride, gallium aluminum nitride, or gallium indium aluminum nitride.

Refer to FIG. 4B. Next, a current blocking layer 60 is formed on the first N-type semiconductor layer 11. The current blocking layer 60 has a pattern. The current blocking layer 60 is made of metal oxide. In one embodiment, the current blocking layer 60 is made of a material selected from a group consisting of titanium dioxide and silicon dioxide. The current blocking layer 60 has a thickness of 10-500 nm.

Refer to FIG. 4C. Next, a second N-type semiconductor layer 12 is laterally grown on the first N-type semiconductor layer 11 to cover and conceal the current blocking layer 60. The second N-type semiconductor layer 12 is also made of silicon-doped gallium nitride, gallium aluminum nitride or gallium indium aluminum nitride.

Next, a light emitting layer 20 is formed on the second N-type semiconductor layer 12. In one embodiment, the light emitting layer 20 is made of gallium nitride or gallium indium nitride.

Next, a P-type semiconductor layer 30 is formed on the light emitting layer 20. In one embodiment, the P-type semiconductor layer 30 is made of magnesium-doped gallium nitride, gallium aluminum nitride, or gallium indium aluminum nitride.

Next, a metal reflection layer 70 is formed on the P-type semiconductor layer 30. In one embodiment, the metal reflection layer 70 is made of a material selected from a group consisting of aluminum, nickel, silver and titanium. The metal reflection layer 70 reflects the light generated by the light emitting layer 20. The metal reflection layer 70 also functions to conduct electricity and dissipate heat.

Next, a barrier layer 80 is formed on the metal reflection layer 70. In one embodiment, the barrier layer 80 is made of a material selected from a group consisting of titanium, tungsten, platinum, nickel, aluminum and chromium. The barrier layer 80 functions to conduct electricity and dissipate heat.

Next, the barrier layer 80 is bonded to a permanent substrate 82 via a bonding layer 81. The barrier layer 80 can prevent the P-type semiconductor layer 30 from being damaged while bonding to the bonding layer 81. The barrier layer 81 also functions to conduct electricity and dissipate heat. In one embodiment, the bonding layer 81 is made of a material selected from a group consisting of gold-tin alloys, gold-indium alloys, and gold-lead alloys. The bonding layer 81 functions to conduct electricity, dissipate heat, and perform adhesion. In one embodiment, the permanent substrate 82 is made of a material selected from a group consisting of silicon, copper, copper-tungsten alloys, aluminum oxide, and titanium nitride. In addition to functioning as a substrate, the permanent substrate 82 also functions to conduct electricity and improve heat-dissipating efficiency.

Refer to FIG. 4D. Next, the temporary substrate 90 and the buffer semiconductor layer 91 are removed, and a P-type electrode 50 is coated on the permanent substrate 82.

Refer to FIG. 4E. Then, the surface 111 of the first N-type semiconductor layer 11 is roughened, and an N-type electrode 40 with the pattern is coated on positions of the roughened surface 111 where the current blocking layer 60 corresponds to.

In the present invention, the current blocking layer 60 is embedded inside the N-type semiconductor layer 10. The current blocking layer 60 not only spreads the current but also controls the contact impedance. Thereby, the contact impedance would not be increased greatly. The method of the present invention can be used to fabricate a vertical structure LED, which needn't adopt a transparent conductive layer with high impedance. Further, as the main light-emitting regions of the light emitting layer 20 are far from the N-type electrode 40, the light shielded by the N-type electrode 40 can be reduced. Therefore, the present invention can effectively promote the luminous efficiency of LED.

What is claimed is:

1. A light-emitting diode with a current diffusion structure, comprising:
an N-type semiconductor layer;
a light emitting layer arranged on one side of the N-type semiconductor layer;
a P-type semiconductor layer arranged on one side of the light emitting layer, which is far from the N-type semiconductor layer;
an N-type electrode including a pattern and arranged on another side of the N-type semiconductor layer, which is far from the light emitting layer;
a P-type electrode arranged on one side of the P-type semiconductor layer, which is far from the light emitting layer; and
a current blocking layer including the pattern of the N-type electrode and embedded inside the N-type semiconductor layer.

2. The light-emitting diode with a current diffusion structure according to claim 1, wherein the current blocking layer is made of metal oxide.

3. The light-emitting diode with a current diffusion structure according to claim 2, wherein the current blocking layer is made of a material selected from a group consisting of titanium dioxide and silicon dioxide.

4. The light-emitting diode with a current diffusion structure according to claim 1, wherein the current blocking layer has a thickness of 10-500 nm.

5. The light-emitting diode with a current diffusion structure according to claim 1, wherein the N-type semiconductor layer includes a first N-type semiconductor layer and a second N-type semiconductor layer, and wherein the current blocking layer is arranged between the first N-type semiconductor layer and the second N-type semiconductor layer.

6. The light-emitting diode with a current diffusion structure according to claim 1, wherein the P-type semiconductor layer and the P-type electrode are interposed by a metal reflection layer, and wherein the metal reflection layer is made of a material selected from a group consisting of aluminum, nickel, silver and titanium.

7. The light-emitting diode with a current diffusion structure according to claim 6, wherein the metal reflection layer and the P-type electrode are interposed by a barrier layer, a bonding layer and a permanent substrate, and wherein the barrier layer is made of a material selected from a group consisting of titanium, tungsten, platinum, nickel, aluminum and chromium, and wherein the bonding layer is made of a material selected from a group consisting of gold-tin alloys, gold-indium alloys and gold-lead alloys, and wherein the permanent substrate is made of a material selected from a group consisting of silicon, copper, copper-tungsten alloys, aluminum nitride and titanium nitride.

8. A method for fabricating a light-emitting diode with a current diffusion structure, comprising steps of:
growing a first N-type semiconductor layer on a temporary substrate;
forming a current blocking layer with a pattern on the first N-type semiconductor layer;
laterally growing a second N-type semiconductor layer on the first N-type semiconductor layer to cover and conceal the current blocking layer;
forming a light emitting layer on the second N-type semiconductor layer;
forming a P-type semiconductor layer on the light emitting layer;
forming a metal reflection layer on the P-type semiconductor layer;
forming a barrier layer on the metal reflection layer;
bonding the barrier layer to a permanent substrate via a bonding layer;
removing the temporary substrate and coating a P-type electrode on the permanent substrate; and
roughening a surface of the first N-type semiconductor layer and coating an N-type electrode with the pattern on positions of the roughened surface where the current blocking layer corresponds to.

9. The method for fabricating a light-emitting diode with a current diffusion structure according to claim 8, wherein the current blocking layer is made of metal oxide.

10. The method for fabricating a light-emitting diode with a current diffusion structure according to claim 9, wherein the current blocking layer is made of a material selected from a group consisting of titanium dioxide and silicon dioxide.

11. The method for fabricating a light-emitting diode with a current diffusion structure according to claim 8, wherein the current blocking layer has a thickness of 10-500 nm.

12. The method for fabricating a light-emitting diode with a current diffusion structure according to claim 8, wherein the metal reflection layer is made of a material selected from a group consisting of aluminum, nickel, silver and titanium.

13. The method for fabricating a light-emitting diode with a current diffusion structure according to claim 8, wherein the barrier layer is made of a material selected from a group consisting of titanium, tungsten, platinum, nickel, aluminum and chromium, and wherein the bonding layer is made of a material selected from a group consisting of gold-tin alloys, gold-indium alloys and gold-lead alloys, and wherein the permanent substrate is made of a material selected from a group consisting of silicon, copper, copper-tungsten alloys, aluminum nitride and titanium nitride.

14. The method for fabricating a light-emitting diode with a current diffusion structure according to claim 8, wherein a buffer semiconductor layer is formed on the temporary substrate before the first N-type semiconductor layer is grown on the temporary substrate, and wherein the buffer semiconductor layer is removed together with the temporary substrate.
